(19) United States
(12) Patent Application Publication
(10) Pub. No.: US 2026/0282341 A1
(43) Pub. Date: Sep. 17, 2026

(54) SEMICONDUCTOR DEVICE AND METHOD FOR FABRICATING THEREOF

(71) Applicant: NANYA TECHNOLOGY CORPORATION, New Taipei City (TW)

(72) Inventor: Yu-Wen CHEN, New Taipei City (TW)

(21) Appl. No.: 19/075,802

(22) Filed: Mar. 11, 2025

(51) Int. Cl. H10B 12/00

(52) U.S. Cl. CPC H10B 12/488; H10B 12/02; H10B 12/482

(57) ABSTRACT

A method of fabricating a semiconductor device that includes forming an opening in a substrate layer; forming a semiconductor layer lining the opening of the substrate layer; forming a first dielectric layer lining the semiconductor layer, in which the first dielectric layer is formed with a first temperature and a first hydrogen (H₂) concentration; and forming a second dielectric layer on the first dielectric layer and filling the opening, in which the second dielectric layer is formed with a second temperature different from the first temperature and a second hydrogen (H₂) concentration different from the first hydrogen (H₂) concentration.

### BACKGROUND

Dynamic random-access memory (dynamic RAM or DRAM) is a type of random-access semiconductor memory that stores each bit of data in a memory cell. DRAM is known for its high speed operation, high density, and scalability. However, as the production of DRAM scales up, the manufacturing of DRAM becomes more challenging and more prone to defects. For example, the rough surface of an active area of a semiconductor device may be unfriendly for the alignment with other layers and may possibly lead to an electrical short. Therefore, there is a need for a credible apparatus and fabrication method for a semiconductor device.

### SUMMARY

The disclosure provides a method of fabricating a semiconductor device that includes forming an opening in a substrate layer; forming a semiconductor layer lining the opening of the substrate layer; forming a first dielectric layer lining the semiconductor layer, in which the first dielectric layer is formed with a first temperature and a first hydrogen (H₂) concentration; and forming a second dielectric layer on the first dielectric layer and filling the opening, in which the second dielectric layer is formed with a second temperature different from the first temperature and a second hydrogen (H₂) concentration different from the first hydrogen (H₂) concentration.

In some embodiments, in which the second temperature is lower than the first temperature.

In some embodiments, in which the second temperature is in a range of approximately 650° C.±100° C. and the first temperature is in a range of approximately 850° C.±100° C.

In some embodiments, in which the second hydrogen concentration is higher than the first hydrogen concentration.

In some embodiments, in which the second hydrogen concentration is in a range of approximately 3.0%±1% and the first hydrogen concentration is in a range of approximately 0.2%±1%.

In some embodiments, in which forming the first dielectric layer lining the semiconductor layer reduces a thickness of the semiconductor layer.

In some embodiments, in which the first dielectric layer and the second dielectric layer are formed by different deposition processes.

In some embodiments, in which the first dielectric layer is formed by an in-situ steam generation (ISSG) process.

In some embodiments, in which the second dielectric layer is formed by an atomic layer deposition (ALD) process.

In some embodiments, further comprising forming a memory device in the substrate layer, wherein the memory device comprises a word line structure embedded in the substrate layer.

The disclosure provides a semiconductor device that includes a substrate layer; a memory device over the substrate layer, wherein the memory device comprises a word line structure embedded in the substrate layer; an isolation structure embedded in the substrate layer and adjacent to the word line structure of the memory device, wherein the isolation structure includes: a first dielectric layer; and second dielectric layer over the first dielectric layer; and semiconductor layer lining the isolation structure.

In some embodiments, in which the first dielectric layer and the second dielectric layer are made of a same material.

In some embodiments, in which the same material is silicon oxide.

In some embodiments, in which the first dielectric layer has a thickness of approximately 1.5 nm to 2.0 nm.

In some embodiments, in which the memory device further comprises a capping material over the word line structure and a dielectric liner lining the word line structure and the capping material.

In some embodiments, further comprising a doped region in the substrate layer.

In some embodiments, in which the doped region has a portion connected to a capacitor and another portion connected to a bit line.

In some embodiments, in which the doped region has a vertical length less than a vertical length of the word line structure.

In some embodiments, in which the first dielectric layer is in physical contact with the semiconductor layer.

In some embodiments, in which the semiconductor layer and the substrate layer are made of a same material.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic view of a memory array, in accordance with some embodiments of the present disclosure.

FIG. 2 is a schematic view of a memory cell, in accordance with some embodiments of the present disclosure.

FIG. 3 is a flow chart of a method of fabricating a semiconductor device, in accordance with some embodiments of the present disclosure.

FIGS. 4 to 9 illustrate a method of fabricating a semiconductor device, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

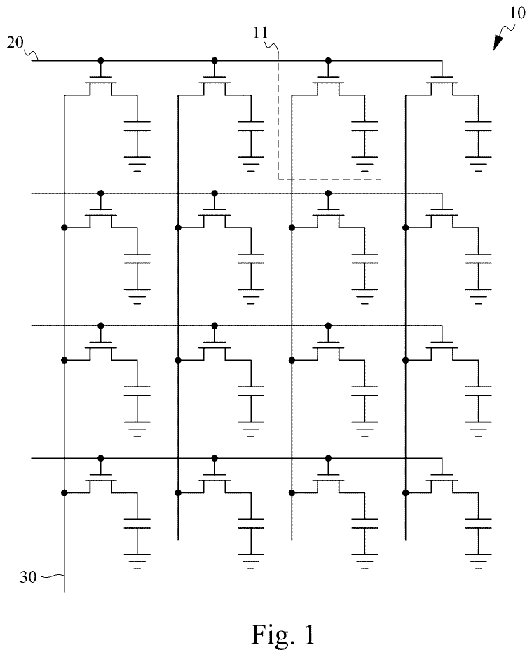

FIG. 1 is a schematic view of a memory array, in accordance with some embodiments of the present disclosure. Shown there is a memory array 10. The memory array 10 includes multiple memory cells 11 laid out in a rectangular matrix. FIG. 1 shows a simple example with a four-by-four cell matrix. Other memory matrices many be thousands of cells in height and width. In some embodiments, the memory array 10 can be a dynamic random-access memory (dynamic RAM or DRAM).

Each row of memory cells 11 is connected by a word line 20 and each column of memory cells 11 is connected by a bit line 30. A plurality of word lines 20 may extend horizontally. The word lines 20 are parallel to each other. Additionally, the word lines 20 may be spaced apart from each other at substantially equal intervals. On the other side, a plurality of bit lines 30 may extend vertically. Similar to the word lines 20, the bit lines 30 are parallel to each other and may be spaced apart from each other at substantially equal intervals.

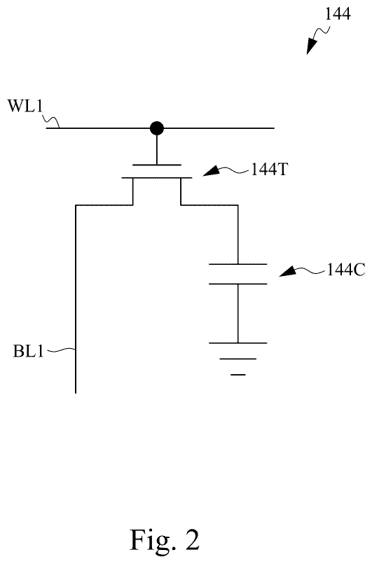

FIG. 2 is a schematic view of a memory cell, in accordance with some embodiments of the present disclosure. Specifically, FIG. 2 is a close-up view of FIG. 1. In some embodiments, a memory cell 144 includes an access transistor 144T and a storage capacitor 144C electrically connected to the access transistor 144T.

In some embodiments, the access transistor 144T is an NMOS transistor, and is configured to control the channel to the memory cell 144 by opening or closing the gate of the access transistor 144T. In some embodiments, the storage capacitor 144C is configured to store information according to the state of electrical charges stored therein. The storage capacitor 144C in an empty state, that is, no charge, is denoted a logic value of 0. The storage capacitor 144C in a fully-charged state is denoted a logic value of 1. The memory cell 144 stores a bit of data by means of the two extreme states of charges stored in the storage capacitor 144C.

In some embodiments, a word line WL1 connected to the access transistor 144T is used to control the gate of the access transistor 144T by applying a voltage to the gate of the access transistor 144T. In some embodiments, a bit line BL1 is arranged perpendicular to the word line WL1 and is also connected to the access transistor 144T. When the gate of the access transistor 144T is turned on, the access transistor 144T connects the storage capacitor 144C to the bit line BL1 such that the logic value stored in the storage capacitor 144C will be read on the bit line BL1.

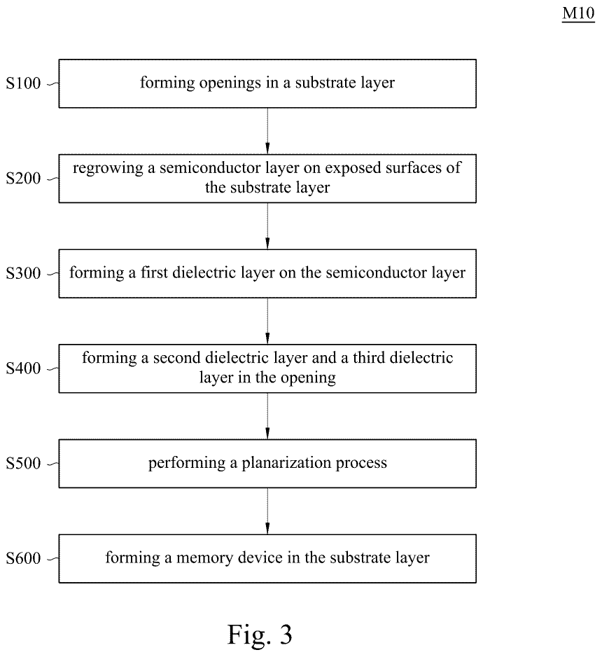

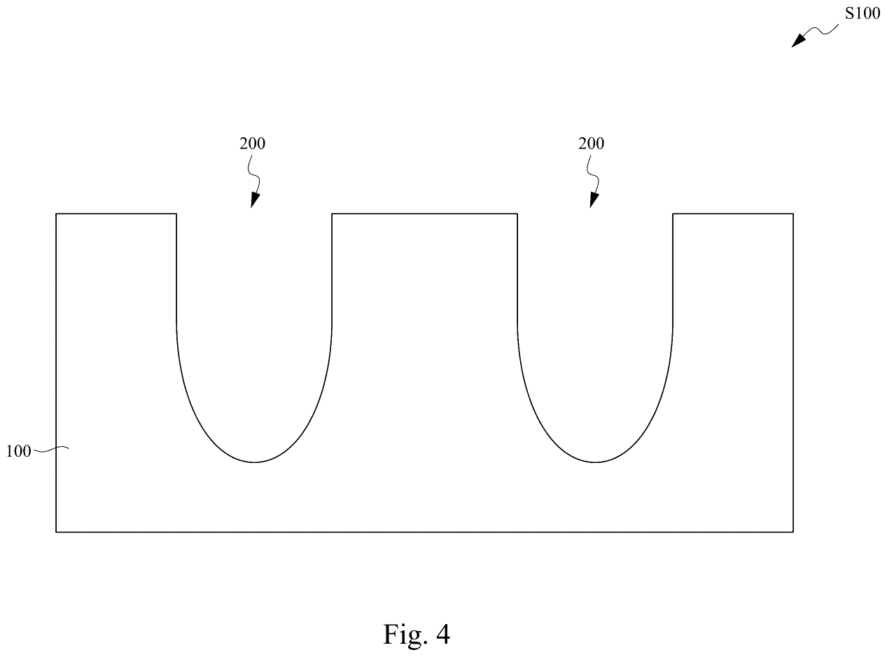

FIG. 3 is a flow chart of a method of fabricating a semiconductor device, in accordance with some embodiments of the present disclosure. FIGS. 4 to 9 illustrate a method of fabricating a semiconductor device, in accordance with some embodiments of the present disclosure.

The semiconductor device and the fabricating method M10 will be discussed in conjunction with reference to FIGS. 4 to 9. As illustrated in FIG. 3, a fabricating method M10 may include the following operations: S100, S200, S300, S400, S500, and S600.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

The method M10 starts from operation S100 by forming openings in a substrate layer. Referring to FIG. 4, the openings 200 are formed in the substrate layer 100.

In some embodiments, the substrate layer 100 is made of silicon (Si). In some embodiments, the substrate layer 100 may include bulk silicon, or another suitable semiconductor material. Illustrative examples of silicon-containing materials suitable for the substrate layer 100 may include, but are not limited to, silicon, silicon germanium, carbon doped silicon germanium, silicon germanium carbide, carbon-doped silicon, silicon carbide, and multi-layers thereof. In some embodiments, the substrate layer 100 may be referred to as a substrate.

The openings 200 can be formed in the substrate layer 100 using suitable patterning process. In some embodiments, a patterned mask layer (not shown) may be formed on top of the substrate layer 100. The patterned mask layer is configured to act as an etch protector for the underneath substrate layer 100 in the subsequent etching process. In some embodiments, the patterned mask layer may not cover the intended region of the openings 200. Subsequently, an etching process may be performed to etch the intended region of the openings 200 through the patterned mask layer. As a result, the openings 200 are formed in the substrate layer 100. In some embodiments, the openings 200 may be regularly arranged at substantially equal intervals from each other horizontally.

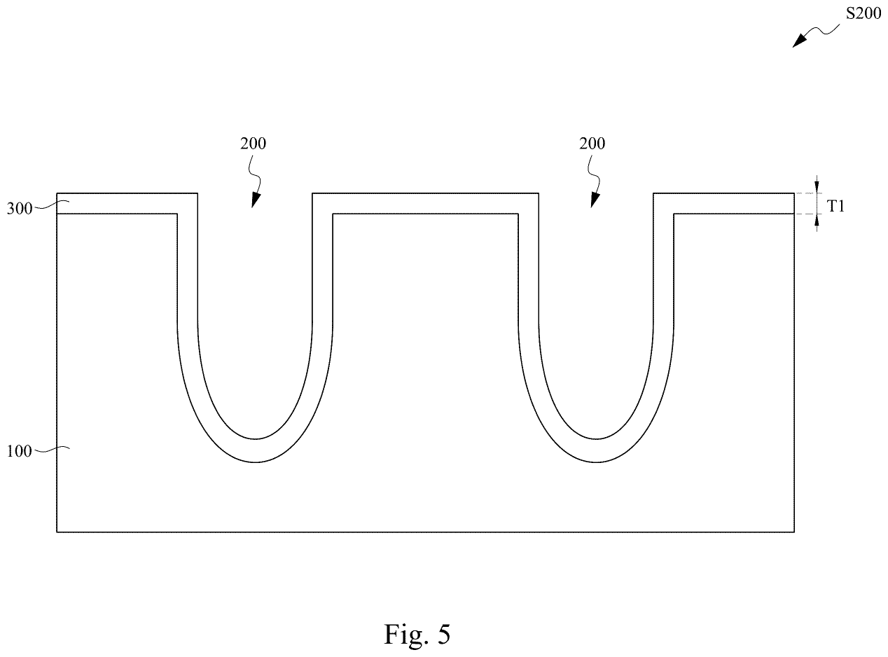

The method M10 proceeds to operation S200 by regrowing a semiconductor layer on exposed surfaces of the substrate layer. Referring to FIG. 5, a semiconductor layer 300 is formed on the substrate layer 100 and along the sidewalls of the openings 200. In some embodiments, the semiconductor layer 300 has a thickness T1.

The semiconductor layer 300 may be deposited by using chemical vapor deposition (CVD), plasma-enhanced chemical vapor deposition (PECVD), atomic layer deposition (ALD), physical vapor deposition (PVD), low-pressure chemical vapor deposition (LPCVD), flowable chemical vapor deposition (FCVD), or other suitable deposition processes.

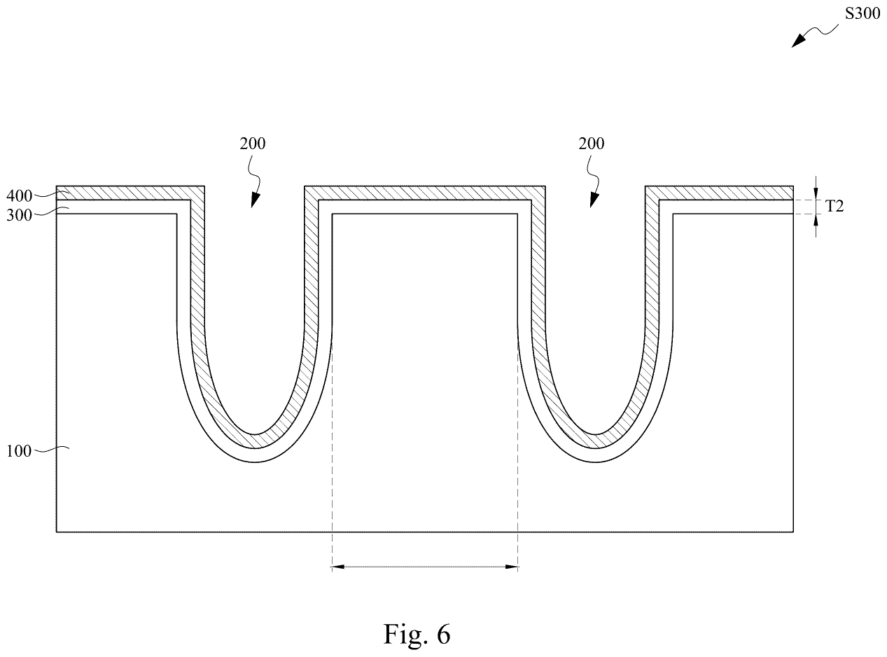

In some embodiments, the regrown semiconductor layer 300 is configured to provide a smoother surface than the surface of the substrate layer 100. Moreover, the regrown semiconductor layer 300 can also act as a buffer layer for the following formed dielectric layer (e.g., the dielectric layer 400 of FIG. 6). In some embodiments, the vertical thickness of the semiconductor layer 300 may be less than the vertical thickness of the substrate layer 100.

In some embodiments, the semiconductor layer 300 is made of the same material as the substrate layer 100. In some embodiments, the semiconductor layer 300 is made of silicon (Si). In some embodiments, the semiconductor layer 300 may include bulk silicon, or another suitable semiconductor material. Illustrative examples of silicon-containing materials suitable for the semiconductor layer 300 may include, but are not limited to, silicon, silicon germanium, carbon doped silicon germanium, silicon germanium carbide, carbon-doped silicon, silicon carbide, and multi-layers thereof.

The method M10 proceeds to operation S300 by forming a first dielectric layer on the semiconductor layer. Referring to FIG. 6, the first dielectric layer 400 is formed on the semiconductor layer 300.

In some embodiments, the first dielectric layer 400 is formed by an in-situ steam generation (ISSG) process. The ISSG process performs an in-situ rapid thermal annealing process on the top surface of the semiconductor layer 300, uses oxygen mixed with a small amount of hydrogen as a reaction gas, and performs a combustion-like chemical reaction on the surface of the semiconductor layer 300 at a high temperature, in which a large amount of oxygen free radicals are generated, so that the silicon on the surface of the semiconductor layer 300 is rapidly oxidized into silicon dioxide (SiO₂), and the first dielectric layer 400 is formed on the semiconductor layer 300. In some embodiments, the first dielectric layer 400 is formed by an in-situ process, and thus the first dielectric layer 400 and the semiconductor layer 300 may be formed in the same chamber. The formation of the first dielectric layer 400 by the ISSG technique is not only fast, but also has a small thermal budget and great temperature uniformity.

In some embodiments, the ISSG process may be performed in a temperature range of approximately 850° C.±100° C. In some embodiments, the ISSG process may be performed in a hydrogen (H₂) concentration range of approximately 0.2%±1%. In some embodiments, the formation of the first dielectric layer 400 with the temperature range of approximately 850° C.±100° C. and the hydrogen concentration range of approximately 0.2%±1% prevents the deformation and migration of the underneath semiconductor layer 300 and/or the substrate layer 100.

Specifically, the formation of the layer that will be formed in the subsequent steps may affect the shape of the top surface of the semiconductor layer 300 and/or the substrate layer 100 and the rough surface of the semiconductor layer 300 and/or the substrate layer 100 may be unfriendly for the alignment with other layers and may possibly lead to an electrical short. However, with the formation of the first dielectric layer 400, this issue can be prevented or mitigated.

In some embodiments, the first dielectric layer 400 is made of a material different from the material of the semiconductor layer 300. In some embodiments, the first dielectric layer 400 is made of a dielectric material. In some embodiments, the first dielectric layer 400 is made of silicon oxide. In some embodiments, the first dielectric layer 400 is made of silicon dioxide (SiO₂).

In some embodiments, the vertical thickness of the first dielectric layer 400 may be less than the vertical thickness of the substrate layer 100. In some embodiments, the first dielectric layer 400 has a vertical thickness of approximately 1.5 nm to 2.0 nm. In some embodiments, the first dielectric layer 400 is configured to provide a smooth surface between the semiconductor layer 300 and the first dielectric layer 400. In some embodiments, the semiconductor layer 300 has a substantially smooth top profile after the formation of the first dielectric layer 400. In some embodiments, the first dielectric layer 400 substantially completely adheres to the semiconductor layer 300.

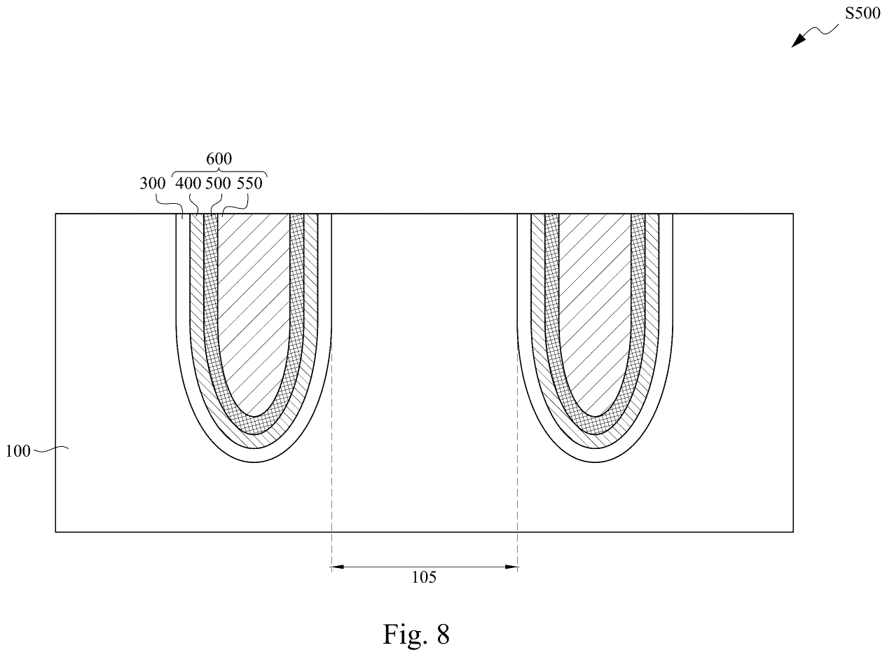

In some embodiments, the region from an opening 200 to another opening 200 may be referred as an active area 105. In some embodiments, an active area is defined by an isolation structure (e.g., the isolation structure 600 shown in FIG. 8), located in the substrate layer 100. In some embodiments, an active area 105 with a smaller pitch is more prone to an electrical short with another active area 105.

The semiconductor layer 300 can also act as a buffer layer for the ISSG process. In some embodiments, the semiconductor layer 300 may be consumed during the ISSG process. As a result, the thickness T1 of the semiconductor layer 300 may be reduced to thickness T2 once the ISSG process is complete, in which the thickness T2 is less than the thickness T1. If the semiconductor layer 300 is omitted, the ISSG process may consume the exposed portion of the substrate layer 100, and will result in an enlargement of the openings 200, and the dimension of the active area 105 cannot be controlled precisely.

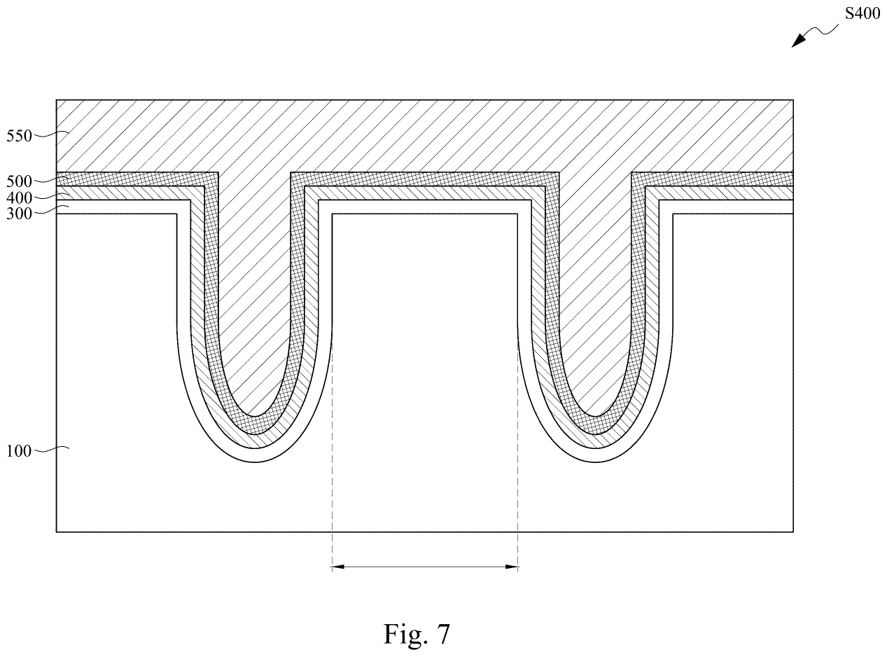

The method M10 proceeds to operation S400 by forming a second dielectric layer and a third dielectric layer in the opening. Referring to FIG. 7, a second dielectric layer 500 and a third dielectric layer 550 are formed in the opening 200. In greater detail, the second dielectric layer 500 is formed lining the first dielectric layer 400, and the third dielectric layer 550 is formed over the second dielectric layer 500 and overfilling the opening 200.

In some embodiments, the second dielectric layer 500 and the third dielectric layer 550 may be deposited by using CVD, PECVD, ALD, PVD, LPCVD, FCVD, or other suitable deposition processes. In some embodiments, the second dielectric layer 500 and the third dielectric layer 550 may be deposited using a different deposition method than the first dielectric layer 400. For example, the first dielectric layer 400 is deposited using an ISSG process, while the second dielectric layer 500 and the third dielectric layer 550 are deposited using an ALD process. In some embodiments, the formation of the first dielectric layer 400 and the formation of the second dielectric layer 500 may be performed under different temperatures and different hydrogen concentrations.

In some embodiments, the formation of the second dielectric layer 500 may be performed in a temperature lower than that of the formation of the first dielectric layer 400. In some embodiments, the formation of the second dielectric layer 500 may be performed in a temperature range of approximately 650° C.±100° C.

In some embodiments, the formation of the second dielectric layer 500 may be performed in a hydrogen concentration higher than that of the formation of the first dielectric layer 400. In some embodiments, the formation of the second dielectric layer 500 may be performed in a hydrogen concentration range of approximately 3.0%±1%.

In-Situ Steam Generation (ISSG) is a thermal oxidation technique employed primarily for growing high-quality silicon dioxide layers directly on silicon wafers. In the ISSG process, hydrogen and oxygen gases are introduced into a chamber, where they react to form steam at elevated temperatures. This steam subsequently oxidizes the silicon layer (e.g., the semiconductor layer 300), forming a silicon dioxide layer (e.g., the first dielectric layer 400) over the silicon layer. ISSG allows for precise control over oxide thickness and offers excellent film quality with high uniformity and low defect density. In some embodiments, a silicon source (e.g., silicon precursor) may not be used in the ISSG process.

On the other hand, Atomic Layer Deposition (ALD) is a highly precise and controlled thin film deposition technique that operates through a sequential, self-limiting chemical reaction process. In ALD process, a substrate is exposed to alternating precursor gases in cycles, typically consisting of two steps: the first step involves the introduction of a precursor (e.g., silicon containing precursor) gas that adsorbs onto the substrate surface, forming a monolayer. The excess precursor is then purged from the chamber. In the second step, a reactant gas (e.g., oxygen-containing precursor) is introduced to interact with the adsorbed precursor layer, forming a thin film monolayer of the desired material. This cycle is repeated to achieve the desired film thickness. The ALD process is characterized by its ability to control film thickness at the atomic scale, resulting in uniform coatings even on complex three-dimensional structures.

In some embodiments, the second dielectric layer 500 is made of the same material as the first dielectric layer 400. In some embodiments, the second dielectric layer 500 is made of a dielectric material. In some embodiments, the second dielectric layer 500 is made of silicon oxide. In some embodiments, the second dielectric layer 500 is made of silicon dioxide (SiO₂). In some embodiments, the third dielectric layer 550 is made of a dielectric material that is different from the materials of the first dielectric layer 400 and the second dielectric layer 500. For example, the third dielectric layer 550 is made of silicon nitride (SiN).

The method M10 proceeds to operation S500 by performing a planarization process. Referring to FIG. 8, a planarization process such as chemical mechanical polishing (CMP) may be performed to remove excess materials of the semiconductor layer 300, the first dielectric layer 400, and the second dielectric layer 500 so that the top surface of the second dielectric layer 500, the top surface of the first dielectric layer 400, and the top surface of the substrate 100 are coplanar. As a result, a plurality of isolation structures 600 are formed, in which each of the isolation structures 600 includes a first dielectric layer 400, a second dielectric layer 500 over the first dielectric layer 400, and a third dielectric layer 550 over the second dielectric layer 500.

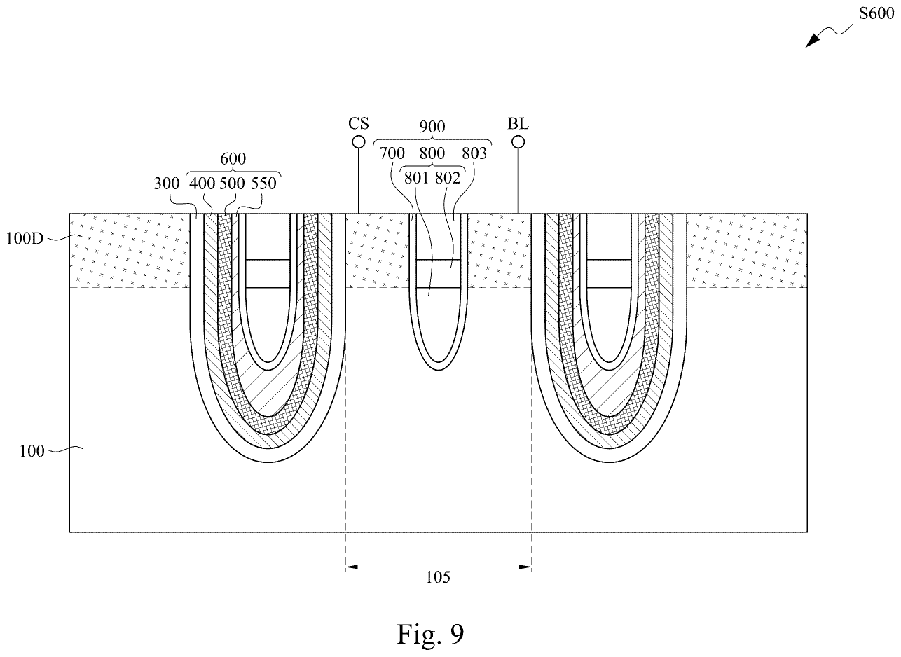

In some embodiments, the isolation structure 600 is configured to provide an electrical isolation between the substrate layer 100 and other conductive structure that may be formed in the subsequent steps (e.g., the memory device 900 shown in FIG. 9). In some embodiments, the second dielectric layer 500 is a shallow trench isolation (STI) structure. In some embodiments, the lateral width of the second dielectric layer 500 may be greater than that of the first dielectric layer 400.

The method M10 proceeds to operation S600 by forming a memory device in the substrate layer. Referring to FIG. 9, a memory device 900 is formed in the substrate layer 100.

After the isolation structures 600 are formed, a doped region 100D may be formed in the substrate layer 100 through an implantation process. In some embodiments, the implantation process is performed in an upper portion of the substrate layer 100. In some embodiments, the doped region 100D has a vertical length less than the vertical length of the isolation structure 600.

Then, a plurality of openings may be formed in the isolation structure 600 and/or the substrate layer 100. In some embodiments, a patterned mask (e.g., photoresist) is formed over the isolation structure 600 and/or the substrate layer 100, in which the patterned mask may include openings that define the positions of the memory devices 900. Afterwards, an etching process may be performed to the openings of the patterned mask to remove portions of the substrate layer 100 and the isolation structures 600.

In some embodiments, the etching process may be suitable etching process, such as wet etch or dry etch. In some embodiments, the anisotropic etching process may be performed, such as reactive ion etching (RIE), deep reactive ion etching (DRIE), or the like. In some embodiments, the aspect ratio of the openings in the substrate layer 100 may be different from (or the same as) the aspect ratio of the openings in the isolation structures 600.

Then, dielectric liners 700, word line structures 800, capping material 803 are formed in the openings mentioned above. The word line structure 800 includes a bottom conductive material 801 and a top conductive material 802 over the bottom conductive material 801.

In some embodiments, a first deposition process may be performed to form a material of the dielectric liner 700 over the substrate layer 100 or the isolation structure 600 and lining sidewalls of the openings. In some embodiments, the first deposition process may be a suitable deposition method, such as CVD, PECVD, low pressure CVD (LPCVD), ultra-high vacuum CVD (UHVCVD), atomic layer deposition (ALD), or the like.

Then, a second deposition process may be performed to form a material of the bottom conductive material 801 over the dielectric liner 700 and overfilling the openings. Then, an etching back process is performed to lower the top surface of the material of the bottom conductive material 801. The bottom conductive material 801 is defined after the etching back process.

Then, a third deposition process may be performed to form a material of the top conductive material 802 and overfilling the openings. Then, an etching back process is performed to lower the top surface of the material of the top conductive material 802. The top conductive material 802 is defined after the etching back process. In some embodiments, the bottom conductive material 801 and the top conductive material 802 can be together referred as a word line structure 800. In some embodiments, the word line structure 800 may function as a gate structure of an access transistor of a memory device.

Finally, a fourth deposition process may be performed to form a material of the capping material 803 and overfilling the openings. Then, a planarization process, such as CMP, may be performed to the material of the capping material 803 until the substrate layer 100 is exposed. The capping material 803 is defined after the planarization process. In some embodiments, the capping material 803 includes a dielectric material.

As a result, a top surface of the substrate layer 100, a top surface of the dielectric liner 700, a top surface of the capping material 803, a top surface of the semiconductor layer 300, and a top surface of the isolation structure 600 are substantially coplanar. In some embodiments, a cleaning process may be performed after the planarization process.

The memory device 900 may include the dielectric liner 700, the word line structure 800 and the capping material 803. In some embodiments, forming the memory device 900 further includes forming a capacitor CS and a bit line BL electrically connected to the doped region 100D. As shown in FIG. 8, the memory device 900 has a portion of the doped region 100D connected to a capacitor CS and another portion connected to a bit line BL.

To sum up, the present disclosure provides a method by performing the additional semiconductor layer 300 and first dielectric layer 400 deposition processes to prevent the deformation and migration of the substrate layer 100, and to facilitate the tight alignment or adhesion with the second dielectric layer 500 by providing a substantially smooth contact surface between the semiconductor layer 300 and the first dielectric layer 400. Accordingly, an electrical short among different active areas 105 may be prevented, and thus the device performance may be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of fabricating a semiconductor device, comprising:
forming an opening in a substrate layer;
forming a semiconductor layer lining the opening of the substrate layer;
forming a first dielectric layer lining the semiconductor layer, wherein the first dielectric layer is formed with a first temperature and a first hydrogen (H₂) concentration; and
forming a second dielectric layer on the first dielectric layer and filling the opening, wherein the second dielectric layer is formed with a second temperature different from the first temperature and a second hydrogen (H₂) concentration different from the first hydrogen (H₂) concentration.

2. The method of claim 1, wherein the second temperature is lower than the first temperature.

3. The method of claim 2, wherein the second temperature is in a range of approximately 650° C.±100° C. and the first temperature is in a range of approximately 850° C.±100° C.

4. The method of claim 1, wherein the second hydrogen concentration is higher than the first hydrogen concentration.

5. The method of claim 4, wherein the second hydrogen concentration is in a range of approximately 3.0%±1% and the first hydrogen concentration is in a range of approximately 0.2%±1%.

6. The method of claim 1, wherein forming the first dielectric layer lining the semiconductor layer reduces a thickness of the semiconductor layer.

7. The method of claim 1, wherein the first dielectric layer and the second dielectric layer are formed by different deposition processes.

8. The method of claim 7, wherein the first dielectric layer is formed by an in-situ steam generation (ISSG) process.

9. The method of claim 7, wherein the second dielectric layer is formed by an atomic layer deposition (ALD) process.

10. The method of claim 1, further comprising forming a memory device in the substrate layer, wherein the memory device comprises a word line structure embedded in the substrate layer.

11. A semiconductor device, comprising:
a substrate layer;
a memory device over the substrate layer, wherein the memory device comprises a word line structure embedded in the substrate layer;
an isolation structure embedded in the substrate layer and adjacent to the word line structure of the memory device, wherein the isolation structure comprises:
a first dielectric layer; and
a second dielectric layer over the first dielectric layer; and
a semiconductor layer lining the isolation structure.

12. The semiconductor device of claim 11, wherein the first dielectric layer and the second dielectric layer are made of a same material.

13. The semiconductor device of claim 12, wherein the same material is silicon oxide.

14. The semiconductor device of claim 11, wherein the first dielectric layer has a thickness of approximately 1.5 nm to 2.0 nm.

15. The semiconductor device of claim 11, wherein the memory device further comprises a capping material over the word line structure and a dielectric liner lining the word line structure and the capping material.

16. The semiconductor device of claim 11, further comprising a doped region in the substrate layer.

17. The semiconductor device of claim 16, wherein the doped region has a portion connected to a capacitor and another portion connected to a bit line.

18. The semiconductor device of claim 16, wherein the doped region has a vertical length less than a vertical length of the word line structure.

19. The semiconductor device of claim 11, wherein the first dielectric layer is in physical contact with the semiconductor layer.

20. The semiconductor device of claim 11, wherein the semiconductor layer and the substrate layer are made of a same material.
